(19) United States
(12) Patent Application Publication
(10) Pub. No.: US 2025/0140583 A1
(43) Pub. Date: May 1, 2025

(54) HEATER BLOCK AND APPARATUS FOR HEATING SUBSTRATE HAVING THE SAME

(71) Applicant: AP SYSTEMS INC., Hwaseong-Si (KR)

(72) Inventors: Dae Ryong LEE, Hwaseong-si (KR); Sung Chul KIM, Hwaseong-si (KR); Sang Hyun JI, Yongin-si (KR); Chang Kyo KIM, Hwaseong-si (KR)

(21) Appl. No.: 18/820,118

(22) Filed: Aug. 29, 2024

(30) Foreign Application Priority Data
Oct. 27, 2023 (KR) 10-2023-0145508

(51) Int. Cl. H01L 21/67

(52) U.S. Cl. CPC H01L 21/67115

(57) ABSTRACT

The present disclosure relates to a heater block and an apparatus for heating a substrate having the same, and more particularly, to a heater block having excellent heat dissipation characteristics and capable of precisely controlling a heating temperature, and an apparatus for heating a substrate having the same. A heater block according to an exemplary embodiment includes a cooling plate provided with a cooling passage through which cooling water flows, a plurality of light emitting modules provided on a first surface of the cooling plate to emit light toward an object to be heated, and a plurality of power supply modules provided on a second surface of the cooling plate and electrically connected to the plurality of light emitting modules by passing through the cooling plate to supply power.

### CROSS-REFERENCE TO RELATED APPLICATION

This application claims priority to Korean Patent Application No. 10-2023-0145508 filed on Oct. 27, 2023 and all the benefits accruing therefrom under 35 U.S.C. § 119, the contents of which are incorporated by reference in their entirety.

### BACKGROUND

The present disclosure relates to a heater block and an apparatus for heating a substrate having the same, and more particularly, to a heater block having excellent heat dissipation characteristics and capable of precisely controlling a heating temperature, and an apparatus for heating a substrate having the same.

A semiconductor element is formed by repeating several unit processes of processing a substrate such as ion implantation, thin film deposition, and heat treatment. In the unit processes, it is necessary to supply thermal energy to process the substrate at a specified process temperature. In particular, since a heating process is carried out for a short period of time by using light energy to heat the substrate to a predetermined process temperature, it has an advantage of minimizing side effects of generating impurities and thus is widely used.

In a typical substrate heating device, a substrate is thermally treated through a heater including a plurality of halogen lamps in a state in which the substrate is seated within a chamber, and a temperature of the substrate is measured in a non-contact manner through a temperature measurement device such as a pyrometer. The pyrometer may collect radiant energy emitted from the substrate to measure the temperature of the substrate in the non-contact manner based on a blackbody radiation temperature relationship. The temperature measured by the temperature measurement device is fed back to a heater block through a heating controller, thereby controlling a temperature of the heater.

In case of a silicon wafer, if the silicon wafer, which has translucent light transmittance at a temperature of approximately 600° C. or less and has characteristic of transmitting light in a low-temperature range due to the nature of the material, is used as the substrate, a portion of the light from the halogen lamp is transmitted through the substrate at a substrate temperature of approximately 600° C. or less, and the pyrometer having a measurement wavelength band of approximately 0.9 μm to approximately 1 μm measures a portion of the light from the halogen lamp having a radiation wavelength of approximately 0.4 μm to approximately 6 μm, which is transmitted through the substrate, and thus, an accurate temperature of only the substrate is not measured, and a temperature measurement error occurs.

In addition, since the halogen lamp is not divided into a plurality of control areas, more precise control for each control area is impossible. As a result, a heater technology capable of controlling each of the control areas, each of which has a smaller area than that of the halogen lamp, is required.

### PRIOR ART DOCUMENT

### Patent Document

(Patent Document 1) Korean Patent No. 10-0974013

### SUMMARY

The present disclosure provides a heater block having excellent heat dissipation characteristics by effectively removing heat generated from a plurality of light emitting modules and an apparatus for heating a substrate having the same.

The present disclosure also provides a heater block capable of controlling a precise heating temperature and supplying power for each of a plurality of control areas to improve temperature uniformity, and an apparatus for heating a substrate having the same.

In accordance with an exemplary embodiment, a heater block includes: a cooling plate provided with a cooling passage through which cooling water flows; a plurality of light emitting modules provided on a first surface of the cooling plate to emit light toward an object to be heated; and a plurality of power supply modules provided on a second surface of the cooling plate and electrically connected to the plurality of light emitting modules by passing through the cooling plate to supply power.

Each of the plurality of power supply modules may include: a terminal part connected to an external power source to receive power; a body part configured to support the terminal part; and an electrode rod part electrically connected to the terminal part to extend from a bottom surface of the body part, wherein the electrode rod part may be connected to the corresponding light emitting module by passing through the cooling plate.

Each of the plurality of light emitting modules may include a first light emitting part and a second light emitting part, which emit light independently of each other, the terminal part may include a first terminal part and a second terminal part, which receive power supplied to the first light emitting part and the second light emitting part, respectively, and the electrode rod part may include a first electrode rod part and a second electrode rod part, which are electrically connected to the first terminal part and the second terminal part, respectively.

The cooling plate may include: a first plate provided with a plurality of upper protrusions protruding from top surfaces to define a side surface of the cooling passage; and a second plate provided on the first plate to be coupled to each other and configured to define a top surface of the cooling passage.

The cooling plate may further include a plurality of first through-holes passing through areas provided by the plurality of upper protrusions, wherein some of the plurality of power supply modules may be inserted into the plurality of first through-holes so as to be electrically connected to the plurality of corresponding light emitting modules.

The cooling plate may include: a plurality of second through-holes passing through areas provided by the plurality of upper protrusions; and a plurality of fixing members that are at least partially inserted into the plurality of second through-holes to fix the plurality of light emitting modules or the plurality of power supply modules.

The first plate may further include a lower protrusion protruding from a bottom surface to define a recess in which each of the plurality of light emitting modules is mounted.

Each of the plurality of light emitting modules and the plurality of power supply modules may have a polygonal shape.

The plurality of light emitting modules and the plurality of power supply modules may be arranged two-dimensionally to provide an array shape having a honeycomb structure.

Each of the plurality of light emitting modules may include: a light emitting semiconductor element configured to emit light; an electric circuit wiring part configured to transmit the power supplied from the plurality of power supply modules to the light emitting semiconductor element; and a metal plate configured to support the electric circuit wiring part and made of a thermal conductive metal.

The light emitting semiconductor element may include a vertical-cavity surface-emitting laser element and is flip-chip bonded to the electric circuit wiring part.

The metal plate may be electrically short-circuited with the light emitting semiconductor element and the electric circuit wiring part.

The heater block may further include a heat dissipation pad provided between the cooling plate and the plurality of light emitting modules and having elasticity.

In accordance with another exemplary embodiment, an apparatus for heating a substrate include: a chamber configured to provide a heat treatment space; a substrate support configured to support the substrate provided in the heat treatment space; and the heater block of any one of claims 1 to 13, which is provided to face the substrate support so as to emit light to a first surface of the substrate and heat the substrate.

The apparatus may further include a pyrometer provided on a second surface of the substrate facing the first surface to measure a temperature of the substrate.

The apparatus may further include a heating controller configured to selectively control the power supplied to each of the plurality of power supply modules based on the temperature measured by the pyrometer.

### BRIEF DESCRIPTION OF THE DRAWINGS

Exemplary embodiments can be understood in more detail from the following description taken in conjunction with the accompanying drawings, in which:

FIG. 1 is a cross-sectional view of a heater block according to an exemplary embodiment;

FIG. 2 is a partial perspective view illustrating an assembled state of the hater block according to an exemplary embodiment;

FIG. 3 is a view illustrating a detailed inner structure of a cooling plate according to an exemplary embodiment;

FIG. 4 is a partial cross-sectional view illustrating a mounted state of a light emitting semiconductor element according to an exemplary embodiment; and

FIG. 5 is a view illustrating a configuration of an apparatus for heating a substrate according to another exemplary embodiment.

### DETAILED DESCRIPTION OF EMBODIMENTS

Hereinafter, specific embodiments will be described in more detail with reference to the accompanying drawings. The present inventive concept may, however, be embodied in different forms and should not be construed as limited to the embodiments set forth herein. Rather, these embodiments are provided so that this disclosure will be thorough and complete, and will fully convey the scope of the present inventive concept to those skilled in the art. In the descriptions, the same elements are denoted with the same reference numerals. In the figures, the dimensions of layers and regions are exaggerated for clarity of illustration. Like reference numerals refer to like elements throughout.

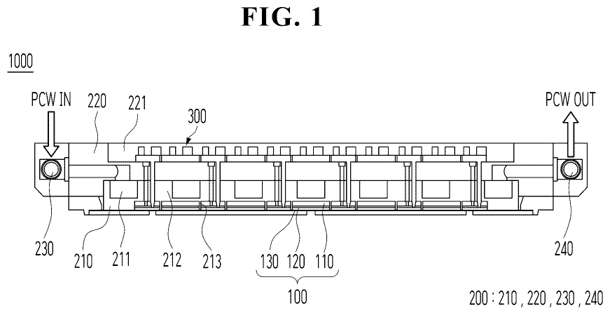

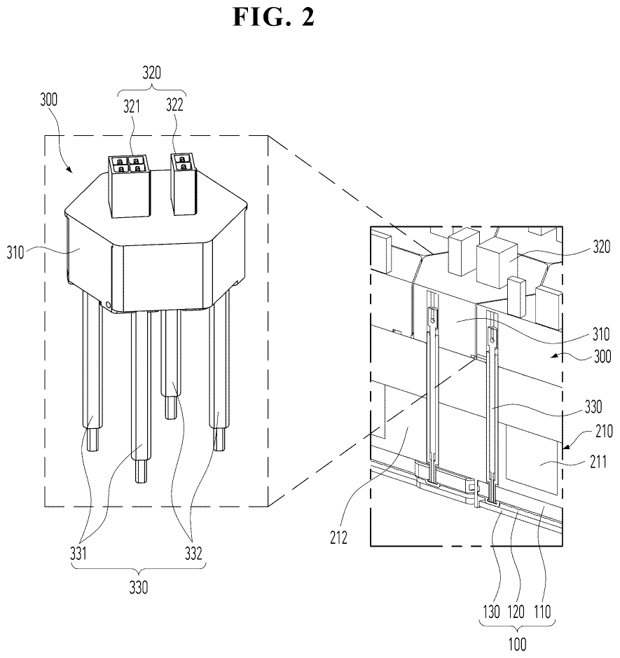

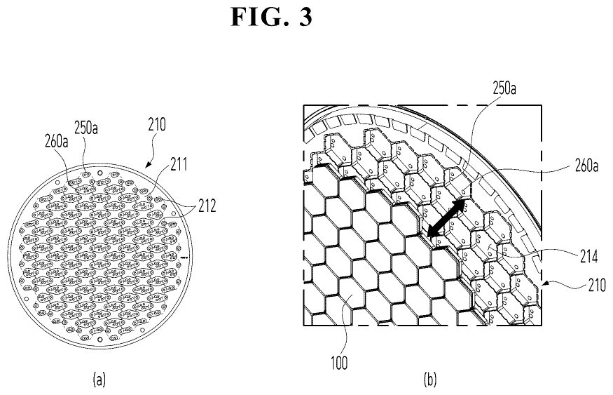

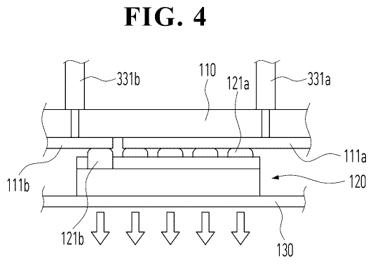

FIG. 1 is a cross-sectional view of a heater block according to an exemplary embodiment, FIG. 2 is a partial perspective view illustrating an assembled state of the hater block according to an exemplary embodiment, FIG. 3 is a view illustrating a detailed inner structure of a cooling plate according to an exemplary embodiment, and FIG. 4 is a partial cross-sectional view illustrating a mounted state of a light emitting semiconductor element according to an exemplary embodiment.

Referring to FIGS. 1 to 4, a heater block 1000 according to an exemplary embodiment may include a cooling plate 200 provided with a cooling passage 211 through which cooling water flows, a plurality of light emitting modules 100 provided on a first surface of the cooling plate 200 to emit light toward an object to be heated (hereinafter, referred to a heated object), and a plurality of power supply modules 300 provided on a second surface of the cooling plate 200 and electrically connected to the plurality of light emitting modules 100 by passing through the cooling plate 200 to supply power.

The heater block 1000 according to an exemplary embodiment may include a light source or a heat source that emits light as a unit for supplying heat energy in various heat treatment apparatuses such as an apparatus for heating a substrate to provide optical energy to the heated object.

The cooling plate 200 may be provided with the cooling passage 211 through which the cooling water flows to absorb ad remove heat energy generated in the plurality of light emitting modules 100 and/or the plurality of power supply modules 300, which are mounted on the cooling plate 200, or transmitted from the heated object, thereby allowing the plurality of light emitting modules 100 and/or the plurality of power supply modules 300 to be maintained to a constant temperature.

The cooling plate 200 may include a cooling water inlet 230 that supplies the cooling water flowing through the cooling passage and a cooling water outlet 240 through which the cooling water heat-exchanged with the plurality of light emitting modules 100 and/or the plurality of power supply modules 300 is discharged. The cooling plate 200 may further include a circulation tube that connects the cooling water inlet 230 to the cooling water outlet 240 to circulate the cooling water, a temperature controller connected to the circulation tube to control a temperature of the cooling water, and a cooling water filter part that remove impurities within the cooling water. Various refrigerants in addition to process cooling water (PCW) or water may be used as the cooling water.

A plurality of light emitting modules 100 may act as a light source or heat source that emits light toward the heated object to heat the heated object, thereby performing the heat treatment. The plurality of light emitting modules 100 may be independently separated from each other and individually mounted or detached from the cooling plate 200. The plurality of light emitting modules 100 may be provided on the first surface of the cooling plate 200 and be in contact with each other, and thus, heat generated in a process of converting electrical energy into light energy by the plurality of light emitting modules 100 may be transferred to the cooling plate 200 and then be removed by being heat-exchanged with each other.

The plurality of power supply modules 300 may be electrically connected to the plurality of corresponding light emitting modules 100 to supply power, and the plurality of power supply modules 300 may individually supply power to the plurality of light emitting modules 100 or may supply power to a group of the light emitting modules in which some of the plurality of light emitting modules 100 are grouped. The plurality of power supply modules 300 may be independently separated from each other and individually mounted or detached from the cooling plate 200. The plurality of power supply modules 300 may be provided on the second surface of the cooling plate 200 so as to be in contact with each other, and thus, the heat generated from the plurality of power supply modules 300 may be transferred to the cooling plate 200 and then be removed by being heat-exchanged with each other.

The plurality of light emitting modules 100 and/or the plurality of power supply modules 300 may be independently separated from each other and individually mounted or detached from the cooling plate 200, and thus, when some of the light emitting modules 100 or the power supply modules 300 are malfunctioned or deteriorated in performance, the corresponding light emitting module 100 or power supply module 300 may be replaced or individually repaired. As a result, the heater block may be conveniently repaired and maintained to be effectively managed in heat.

In the present disclosure, the plurality of light emitting modules 100 and the plurality of power supply modules 300 may be provided to be mounted on the first surface and the second surface of the cooling plate 200, which face each other with respect to the cooling plate 200, and thus, the cooling plate 200 may stably support the plurality of light emitting modules 100 and the plurality of power supply modules 300. Furthermore, the cooling plate 200 may separate the plurality of light emitting modules 100 and the plurality of power supply modules 300 from each other on both surfaces to support the plurality of light emitting modules 100 and the plurality of power supply modules 300, thereby effectively remove the heat generated from the plurality of light emitting modules 100 and the plurality of power supply modules 300 without accumulating the heat. For example, if the plurality of light emitting modules 100 and the plurality of power supply modules 300 are mounted on one surface of the cooling plate 200, the heat generated from the module disposed far from the cooling plate 200 among the plurality of light emitting modules 100 and the plurality of power supply modules 300 may not be dissipated and accumulated on its own. In addition, the heat may be accumulated on contact surfaces of other modules, and thus, the heat may be accumulated without the effective heat dissipation overall.

If the heat generated from the plurality of light emitting modules 100 and the plurality of power supply modules 300 is not effectively dissipated, operations of the plurality of power supply modules 300 and/or the plurality of light emitting modules 100 may be affected by the accumulated heat to cause instability in the supplied power or deterioration in emission output. In addition, the plurality of power supply modules 300 may pass through the cooling plate 200 to supply the power to the plurality of light emitting modules 100, but the electrical connection for supplying the power may be partially short-circuited due to the accumulated heat to cause a limitation in durability of the heater block.

However, in the present disclosure, the cooling plate 200 may be disposed between the plurality of light emitting modules 100 and the plurality of power supply modules 300, and thus, the cooling plate 200 may be in contact with each of the plurality of light emitting modules 100 and the plurality of power supply modules 300 to effectively dissipate the heat generated from the plurality of light emitting modules 100 and the plurality of power supply modules 300.

To improve the temperature uniformity of the heated object such as the substrate, the plurality of light emitting modules 100 and the plurality of power supply modules 300 may be arranged two-dimensionally and selectively controlled for each area. In this case, the heat may be accumulated in a central area of the plurality of light emitting modules 100 and the plurality of power supply modules 300 arranged two-dimensionally, but the cooling plate 200 may suppress the heat accumulation by being directly heat-exchanged with the plurality of light emitting modules 100 and the plurality of power supply modules 300 to effectively dissipate the heat, thereby enabling the precise control of the heating temperature and power supply for each area, thereby improving the temperature uniformity of the heated object.

Each of the plurality of power supply modules 300 that are provided detachably and independently on the second surface of the cooling plate 200 may include a terminal part 320 connected to an external power source to receive the power, a body part 310 that supports the terminal part 320, and an electrode rod part 330 electrically connected to the terminal part 320 to extend from a bottom surface of the body part 310. In addition, the electrode rod part 330 may be connected to the corresponding light emitting module 100 by passing through the cooling plate 200.

The terminal part 320 may be connected to a power line extending from the external power source to receive the power that is necessary to generate the light from the corresponding light emitting module 100. The terminal part 320 may be provided with a connection part into which a socket terminal of the power line is inserted and connected.

The body part 310 may support the terminal part 320 provided on the top surface and may be provided with a wiring part that transmits power supplied to the terminal part 320 to the electrode rod part 330, a switching part that selectively short-circuits the supplied power. The body part 310 may further have a fixing hole into which a fixing member for fixing the power supply module 300 to the cooling plate 200 is inserted.

The electrode rod part 330 electrically connected to the terminal part 320 to extend downward from the bottom surface of the body part 310 may pass through the cooling plate 200 in a thickness direction and be connected to electrode terminal parts 111a and 111b of the corresponding light emitting module 100 to which the power is supplied by the power supply module 300. Since the cooling plate 200 is made of an electrically conductive material (e.g., a metal such as copper or stainless steel) so that the heat is transmitted smoothly, the electrode rod part 330 may include a metal rod part that transmits the power supplied from the terminal part 320 and an insulating coating layer that covers a side surface except for an end of the metal rod part so that the electrode rod part 330 is not electrically short-circuited with the cooling plate 200.

In this specification, the plurality of light emitting modules 100 and the plurality of power supply modules 300 may be used to independently or selectively control the emission states of the plurality of light emitting modules 100 for each area, thereby improving the heating uniformity or the temperature uniformity of the heated object.

To further sub-divide the control area, each of the plurality of light emitting modules 100 may include a first light emitting part and a second light emitting part, which emit light independently of each other. The first light emitting part and the second light emitting part may be provided to equally divide an emission surface of the light emitting module into two surfaces or may be provided to divide the emission surface at different ratios. Each of the first light emitting part and the second light emitting part may include a plurality of light emitting semiconductor elements that provide light energy. The plurality of light emitting semiconductor elements may be provided by mounting a plurality of chips, or a multi-chip may be provided in the form of a single element.

In order for the first light emitting part and the second light emitting part to emit light independently of each other, the terminal part 320 may include a first terminal part 321 and a second terminal part 322, which receive the power supplied to the first and second light emitting parts, respectively, and the electrode rod part 330 may include a first electrode rod part 331 and a second electrode rod part 332, which are electrically connected to the first terminal part 321 and the second terminal part 322. Each of the first electrode rod part 331 and the second electrode rod part 332 may be provided as a pair of positive and negative electrodes and may transmit the power supplied to the first terminal part 321 and the second terminal part 322 through the cooling plate 200 to the corresponding first light emitting part and the second light emitting part.

The cooling plate 200 may include a first plate 210 having a plurality of upper protrusions 212 protruding from top surfaces to define a side surface of the cooling passage 211, and a second plate 220 provided on the first plate 210 to be coupled to each other and configured to define the top surface of the cooling passage 211. That is, the cooling passage 211 may be sufficient as long as the cooling water flows to be surrounded by a top surface of the first plate 210, the upper protrusion 212, and a bottom surface of the second plate, and the structure or the formation position of the upper protrusion 212, etc. (for example, the bottom surface of the second plate 220, etc.) for defining the cooling passage 211 may vary.

In the case in which the cooling passage 211 is a linear passage having a straight or curved shape formed by a pipe or drilling inserted between the cooling water inlet 230 and the cooling water outlet 240, the cooling water may quickly flows along the linear passage from the cooling water inlet 230 toward the cooling water outlet 240, and thus, the cooling water may not have a sufficient time to be heat-exchanged with the first plate and/or the second plate, and inevitably have a temperature gradient (or temperature difference) from the cooling water inlet 230 toward the cooling water outlet 240. On the other hand, if the cooling water flows through a wide empty space defined in a central portion between the first plate and the second plate, which are coupled to each other at an edge or border of the cooling plate 200, an area on which the flowing cooling water is in contact with the first plate and/or the second plate may not be large, and thus, the heat exchange may not occur well.

If the cooling water does not flow along the shortest path (or a path close to the shortest path) between the cooling water inlet 230 provided at one side of the cooling plate 200 and the cooling water outlet 240 provided at the other side of the cooling plate 200 crossing the cooling plate 200, but instead flows while making a continuous detour, a cooling area through the heat exchange of the cooling water may be maximized to improve the heat dissipation effect of the cooling plate 200.

As illustrated in (a) of FIG. 3, which is a plan view illustrating the top surface of the first plate 210, the top surface of the first plate 210 may be provided with a plurality of upper protrusions 212 that define the side surface of the cooling passage 211. The plurality of upper protrusions 212 may be spaced apart from each other and provided on the top surface of the first plate 210 so that an empty space between the plurality of upper protrusions 212 defines the cooling passage 211. When the cooling water is introduced onto the top surface of the first plate 210 through the cooling water inlet 230 provided at one side of the cooling plate 200, the cooling water flowing toward the cooling water outlet 240 provided at the other side of the cooling plate 200 may have no choice but to spread out by bypassing while continuously colliding with the plurality of upper protrusions 212 to effectively increasing in contact area or cooling area between the cooling water and the first plate 210.

The first plate 210 and the second plate 220, which defines the cooling plate 200, may be coupled to each other to be integrated with each other. Since the first plate 210 and the second plate 220 are coupled to not only at the edge but also supported by the upper protrusion 212 therein, the cooling plate 200 may be structurally more stable.

The bottom surface of the second plate 220, which constitutes the cooling plate 200 by being coupled to the first plate 210, may define the top surface of the cooling passage, and the bottom surface of the second plate 220 may be in direct contact with the plurality of upper protrusions 212 so that the heat of the second plate 220 is quickly transferred to the upper protrusions 212. That is, the cooling water may be directly heat-exchanged while being in contact with the top surface of the first plate 210, the upper protrusion 212, and the bottom surface of the second plate 210, and the first plate 210 and the second plate 220 may be thermally connected to each other through the upper protrusion 212 to provide the cooling plate 200 having the integrated structure that is capable of maintaining the uniform temperature. Each of the first plate 210 and the second plate 220 may be made of a metal having high thermal conductivity, and the first plate 210 and the second plate 220 may be coupled to each other by brazing or welding, and thus, the first plate 210 and the second plate 220 may be completely coupled to each other joined so that the heat transfer between the first plate 210 and the second plate 220 occurs more quickly.

Since the light emitting module 100 that functions as the heat source in the heater block 1000 generates more heat than the power supply module 300, it is necessary to dissipate the heat emitted from the light emitting module 100 more quickly. Thus, the plurality of light emitting modules 100 may be provided on the first plate 210 that allows faster heat dissipation by being in contact with the cooling water on the top surface and the upper protrusion 212, and the plurality of power supply modules 300 may be provided on the second plate 220.

The first plate 210 and the second plate 220 may be made of the same material or may be made of different materials. The first plate 210, which requires relatively excellent heat dissipation characteristics, may be made of copper that is a metal having good thermal conductivity characteristics, and the second plate 220, which is capable of reinforcing mechanical stability of the cooling plate 200, may be made of stainless steel that is a metal having excellent mechanical strength and chemical stability.

The cooling plate 200 may further include a plurality of first through-holes 250 passing through the area on which the plurality of upper protrusions 212 are provided, and a portion of the plurality of power supply modules 300 may be inserted into the plurality of first through-holes 250 and electrically connected to the corresponding plurality of light emitting modules 100.

In order for the plurality of power supply modules 300 to pass through the cooling plate 200, thereby supplying the power to the plurality of light emitting modules 100, a portion of the plurality of power supply modules 300 (e.g., the electrode rod part 330) have to pass through the first plate 210 and the second plate 220. If the electrode rod part 330 passes through the area of the cooling passage 211, the electrical short may occur between the electrode rod part 330 and the cooling water, or a water leakage may occur at a position at which the electrode rod part 330 is inserted. In order to solve this limitation, in the present disclosure, the plurality of first through-holes 250 may be defined to pass through the first plate 210 and the second plate 220 on the area on which the upper protrusion 212 is provided, and electrode rod parts 330 of the plurality of power supply modules 300 may be inserted into the plurality of first through-holes 250 so as to be electrically connected to the plurality of corresponding light emitting modules 100. To define the first through-hole 250, a lower first through-hole 250a may be defined through the upper protrusion 212 of the first plate 210 to correspond to the position and number of the electrode rod part 330, and an upper first through-hole 250b may be defined in the area of the second plate 220 to which the upper protrusion 212 is bonded. After coupling the first plate 210 to the second plate 220, the first through-hole 250 may be defined by drilling or the like in an area on which the plurality of upper protrusions 212 are provided.

Since the electrode rod part 330 is inserted into the first through-hole 250 passing through the plurality of protrusions 212, which are the portions at which the first plate 210 and the second plate 220 are bonded to each other, not only the electrode rod part 330 may not be in direct contact with the cooling water, but also the first through-hole 250 may not be exposed to the cooling water, and thus, possibility of the leakage of the cooling water may be eliminated.

The cooling plate 200 may further include a plurality of second through-holes 260 passing through the area on which the plurality of upper protrusions 212 are provided, and a plurality of fixing members that are at least partially inserted into the plurality of second through-holes 260 to fix the plurality of light emitting module 100 or the plurality of power supply module 300.

The plurality of light emitting modules 100 and the plurality of power supply modules 300 may be provided two-dimensionally arranged to face each other on the first and second surfaces of the cooling plate 200. In order for the plurality of light emitting modules 100 and the plurality of power supply modules 300, which correspond to each other, to maintain the electrically connected state, the plurality of light emitting modules 100 and the plurality of power supply modules 300 may need to be stably fixed on the first and second surfaces of the cooling plate 200, respectively.

To prevent the leakage of the cooling water, the plurality of second through-holes 260 may pass through the area on which the plurality of upper protrusions 212 are provided. The second through-hole 260 may completely or partially pass through the cooling plate 200 depending on a method for fixing the plurality of light emitting modules 100 and/or the plurality of power supply modules 300 by inserting the fixing member at least partially.

To define the plurality of second through-holes 260, a lower second through-hole 260a passing through the upper protrusion 212 of the first plate 210 may be defined, and an upper second through-hole 250b may be defined in the area of the second plate 220 to which the upper protrusion 212 is bonded. After coupling the first plate 210 to the second plate 220, the second through-hole 260 may be defined by drilling or the like in an area on which the plurality of upper protrusions 212 are provided.

The plurality of fixing members may be inserted at least partially into the plurality of second through-holes 260, and one end of each of the fixing members of the plurality of fixing members may be inserted and fixed into a fixing groove defined in each of the plurality of light emitting modules 100 or the plurality of power supply modules 300 to fix the plurality of light emitting modules 100 or the plurality of power supply modules 300 to the cooling plate 200. The fixed member may be a nut having a screw thread on an outer surface, and a screw thread corresponding to the screw thread on the outer surface of the fixed member may be disposed on an inner surface of the second through-hole 260 or the fixed groove.

As illustrated in (b) FIG. 3, the first plate 210 may further include a lower protrusion 213 that protrudes from the bottom surface of the first plate 210 to define a recess 214 in which the plurality of light emitting module 100 are mounted.

The plurality of light emitting modules 100 may be provided on the first surface of the cooling plate 100 facing the heated object to emit light toward the heated object. To uniformly the heat the heated object such as the substrate, the plurality of light emitting modules 100 has to be uniformly arranged two-dimensionally on the first surface of the cooling plate 100 (or the bottom surface of the first plate 210). Thus, in the present disclosure, to determine a correct position at which the plurality of light emitting modules 100 are to be mounted, the plurality of light emitting modules 100 may be inserted into and mounted in the plurality of recesses 214 defined between the lower protrusions 213 protruding from the bottom surface of the first plate 210 to enable the plurality of light emitting modules 100 to be uniformly arranged at a predetermined position on the bottom surface of the first plate 210. When the light emitting module 100 is inserted into the recess 214, the heat generated from the light emitting module 100 may be quickly dissipated to the cooling plate 200 not only through the bottom surface of the first plate 210 that is in contact with the bottom surface of the light emitting module 100, but also through the lower protrusion 213 that is in contact with or is close to the side surface of the light emitting module 100.

Similar to the recess 214 that accommodates the plurality of light emitting module 100, the second plate 220 may include a top recess 221 defined in the top surface of the second plate 220 to accommodate the plurality of power supply modules 300. The top recess 221 may be provided as a plurality of top recesses 221 to individually accommodate the plurality of power supply modules 300 or may be provided as a single top recess 221 to accommodate the plurality of power supply modules 300 in their entirety. The second plate 220 may further include a cover (not shown) that covers the top recess 221 to protect the plurality of power supply modules 300 accommodated in the top recess 221.

Each of the plurality of light emitting modules 100 and each of the plurality of power supply modules 300 may have a polygonal shape.

To uniformly heat the heated object such as the substrate, not only the plurality of light emitting modules 100 that are uniformly arranged two-dimensionally, but also the plurality of power supply modules 300 that supply power to the corresponding plurality of light emitting modules 100 by passing through the cooling plate 200 may be uniformly arranged two-dimensionally. Not only the plurality of light emitting modules 100 and the plurality of power supply modules 300 need to be uniformly distributed two-dimensionally, but also a gap between the plurality of light emitting modules 100 and a gap between the plurality of power supply modules 300 need to be two-dimensionally constant. If the gaps between the light emitting modules 100 are different depending on a direction and position, the light emission may not occur in a gap area between the light emitting modules 100, and thus, the light emission may not be uniform across the entire emission surface of the heater block 1000.

In the case in which a planar shape (the outermost shape when viewed from above) of each of the light emitting module 100 and the power supply module 300 is not a polygonal shape but a circular shape, etc., the gap between the light emitting module 100 and the corresponding power supply modules 300, which are adjacent to each other, may vary depending on the direction to enable the uniform light emission. For example, in horizontal and vertical directions, the gap between the adjacent light emitting modules 100 may be minimal, and in a direction that is tilted at approximately 45 degrees, the gap between the adjacent light emitting modules 100 may be maximal.

When the planar shapes of the light emitting module 100 and the corresponding power supply module 300 have the same polygonal shape, not only the plurality of light emitting modules 100 and the plurality of power supply modules 300 be uniformly distributed on both the surfaces of the cooling plate 200, but also the gap between the light emitting module 100 and power supply module 300, which are adjacent to each other, may be maintained constantly. Due to this arrangement structure, the heater block 1000 may provide uniform heat energy or light energy to the heated object.

Referring to FIG. 2 and (b) of FIG. 3, each of the plurality of light emitting modules 100 and the plurality of power supply modules 300 may have a hexagonal shape. When each of the plurality of light emitting modules 100 and the plurality of power supply modules 300 has the hexagonal outermost shape, not only it may easy to be expanded two-dimensionally, but also the entire arrangement of the plurality of light emitting modules 100 or the plurality of power supply modules 300 may define a concentric structure from the center, and thus, the uniform light emission may be achieved regardless of the position on the emission surface of the heater block 1000.

The plurality of light emitting modules 100 and the plurality of power supply modules 300 may be arranged two-dimensionally to provide an array shape having a honeycomb structure.

In the honeycomb structured array in which the plurality of light emitting modules 100 and the plurality of power supply modules 300 having a hexagonal flat shape are arranged two-dimensionally, an entire circumference of the light emitting module 100 may be surrounded by a minimum number (six) of adjacent light emitting modules 100 that are equal to the number of angles in the hexagonal shape. Thus, an average density and luminescence efficiency (or heating efficiency) of the light emitting module 100 per unit area may increase.

If each of the plurality of light emitting modules 100 has the polygonal (e.g., hexagonal) shape, the recesses 214 defined by the lower protrusion part 213 may also be arranged two-dimensionally in the polygonal (e.g., hexagonal) shape.

Each of the plurality of light emitting modules 100 may include a light emitting semiconductor element 120 that emits light, electric circuit wiring parts 111a and 111b that transmit power supplied from the plurality of power supply modules 300 to the light emitting semiconductor element 120, and a metal plate 110 that supports the electric circuit wiring parts 111a and 111b and is made of a thermally conductive metal.

The light emitting semiconductor element 120 may be a semiconductor element that emits light when electrons provided through an n-type semiconductor layer and holes provided through a p-type semiconductor layer are coupled to each other and may include a light emitting diode (LED) or a laser diode (LD). In order to be used as the heat source or light source that supplies energy uniformly to the heated object having a large area in the heater block 1000, it has to have the form of a surface light source having a large area. For this, the light emitting module 100 may need to be provided with the light emitting semiconductor element 120 manufactured in a two-dimensional array shape.

A window 130 that allows the light emitted from the light emitting semiconductor element 120 to pass through and protects the light emitting semiconductor element 120 may be provided on the emission surface of the light emitting semiconductor element 120.

The electric circuit wiring parts 111a and 111b may be provided with a circuit wiring layer made of a conductive metal that transmits power, an insulating layer provided above or below the circuit wiring layer, and an insulating base that supports the circuit wiring layer and the insulating layer and may transmit the power supplied by the electrode rod part 330 of the plurality of power supply modules 300 to the light emitting semiconductor element 120.

The light emitting semiconductor element 120 may include an n-type electrode 121b connected to an n-type semiconductor layer and a p-type electrode 121a connected to a p-type semiconductor layer. The n-type electrode 121b may be electrically connected to an n-type circuit wiring part 111b and an n-type electrode rod part 331b so as to be in a low potential state, and the p-type electrode 121a may be electrically connected to the n-type circuit wiring part 111b and the n-type electrode rod part 331b so as to be in a high potential state.

The light emitting module 100 may be provided on the bottom surface of the first plate 210, but since the light emitting semiconductor element 120 and the electric circuit wiring parts 111a and 111b do not have a thermally conductive material distributed over the entire surface, the light emitting semiconductor element 120 and the electric circuit wiring parts 111a and 111b may not be able to quickly transfer the heat to the bottom surface of the first plate 210. However, in the present disclosure, the metal plate 110 may be configured to integrally support the electric circuit wiring parts 111a and 111b and the light emitting semiconductor element 120 connected thereto and be made of a heat-conductive metal, and thus, the heat generated from the light emitting semiconductor element 120 may be quickly transferred to the first plate 210 so as to be dissipated to the outside. The laminated structure of the electric circuit wiring parts 111a and 111b and the metal plate 110 may be configured in the form of a metal printed circuit board (PCB) if a surface facing the bottom surface of the first plate 210 is an exposed metal surface.

For the rapid heat exchange, the bonding surface of the light emitting module 100 and the first plate 210, which are in contact with each other, may be made of a metal on each of both surfaces. Since the surface structure of the metal surface has roughness, when the metal surfaces may be in contact with each other, a gap may be generated at an interface between the metal surfaces due to the surface roughness. Air filling the gap generated at the interface between the light emitting module 100 and the first plate 210 may have low thermal conductivity, and thus, the thermal conductivity characteristics between the light emitting module 100 and the first plate 210 may be reduced. In particular, when the heater block 1000 is disposed and used in a process space that is maintained in a vacuum state, like the apparatus for heating the substrate, the gap generated at the interface between the light emitting module 100 and the first plate 210 may be in a vacuum state to significantly reduce the heat exchange between the light emitting module 100 and the first plate 210, which may be fatal. To solve this limitation, an elastic heat dissipation pad may be provided between the cooling plate 200 and the plurality of light emitting module 100.

When the heat dissipation pad having the elasticity such as a silicone heat dissipation pad is provided between the light emitting module 100 and the first plate 210, the heat dissipation pad may be filled into the gap generated by the surface roughness of the light emitting module 100 and the first plate 210 while being elastically deformed to increase in thermal contact area between the light emitting module 100 and the first plate 210, thereby effectively improving the heat exchange efficiency. In addition, slip may occur between the metal plate 110 and the first plate 210 to cause a deviation from the proper position for the electrical connection. If the elastic heat dissipation pad is provided between the light emitting module 100 and the first plate 210, the slip may be prevented, and the proper position may be maintained.

As illustrated in (b) of FIG. 3, when the plurality of light emitting modules 100 are inserted into and mounted in the plurality of recesses 216 having the polygonal shape, the heat dissipation pad may be provided in the same polygonal shape as the plurality of light emitting modules 100 and inserted in the plurality of recesses 216. Here, the light emitting pad may have a through-hole corresponding to each of the first through-hole 250 and the second through-hole 260 for the electrical connection and fixation of the plurality of light emitting modules 100.

The light emitting semiconductor element 120 may include a vertical-cavity surface-emitting laser element and may be flip-chip bonded to the electric circuit wiring parts 111a and 111b.

The vertical-cavity surface-emitting laser (VCSEL) element that is used as the light emitting semiconductor element 120 may have a structure in which a laser beam is emitted in a direction perpendicular to the heated object such as the substrate, unlike a side-emitting laser such as a typical distributed feedback laser diode (DFB LD) or Fabri-Perot laser diode (FP LD). Since the laser beam is emitted in the direction perpendicular to the heated object, it may have a circular symmetry distribution, and thus, the light uniformity may be superior to that of the side-emitting laser, and wafer-scale processing and manufacturing using a single silicon wafer (or circular substrate) may be enabled. In addition, since a resonance distance is made very short, the critical current may be reduced, and an overall output may be reduced.

In particular, to be used as the heating light source in the apparatus for heating the substrate, a surface light source having a large area has to be formed. For this, the light emitting semiconductor element 120 may need to be manufactured as a two-dimensional array-type parallel light source. In the case of a side-emitting laser, since the laser emits light through a side surface of the structure laminated on the substrate, it may be difficult to manufacture the two-dimensional array-type parallel light source. On the other hand, a vertical-cavity surface-emitting laser (VCSEL) may be manufactured very easily as the two-dimensional array-type parallel light source in a desired shape because the structure laminated on the substrate is formed into a desired structure.

In addition, the vertical-cavity surface-emitting laser (VCSEL) may have a light source irradiation angle of approximately 20° to approximately 25° with respect to the vertical direction of the emission surface, which is much narrower than the irradiation angle of approximately 30° to approximately 40° of the light emitting diode (LED), and thus, the light may have good straightness. This makes it possible to have the two-dimensional array-type parallel light source capable of emitting high-power and high-precision light onto the heated object as well as emitting the uniform light.

Since the light emitting module 100 provided on the first surface (or bottom surface) of the cooling plate 200 emits light in a direction opposite to the first surface (or downward direction), the light emitting semiconductor element 120 may have an emission surface facing downward.

In the case of wire bonding, which is a method of electrically connecting the light emitting semiconductor element to the electric circuit wiring part, bonding may be generally performed in a lateral direction of the light emitting semiconductor element, and thus, an area may inevitably increase two-dimensionally, resulting in a low element density within the light emitting module. In addition, since the wire is exposed to the outside, it may be difficult to use the wire in the vacuum state, like the apparatus for heating the substrate, due to reasons such as arcing, and since the plurality of wire bonds have be performed, a defect rate may be high. This limitation may be solved by connecting the light emitting semiconductor element 120 to the electric circuit wiring parts 111a and 111b using the flip chip bonding, in which a solder bump is provided on the surface electrode of the semiconductor chip while the semiconductor chip is turned over and then is directly connected to the wiring electrodes through the heat treatment process.

When the light emitting semiconductor element 120 is flip-chip bonded to the terminal parts 111a and 111b of the electric circuit wiring part supplied with power by the electrode rod part 330 connected to a rear surface of the light emitting module 100, an electrical connection portion such as the solder bump may be provided on a front surface (a surface opposite the emission surface) of the light emitting semiconductor element 120, and thus, the element density within the light emitting module 100 may increase. In addition, since the electrical connection such as the solder bump is not exposed to the outside, the heater block 1000 may be applied to a vacuum process and be easy to handle and have excellent reliability and lifespan. In addition, the shortest thermal path from the light emitting semiconductor element 120 to the cooling plate 200 may be formed by the flip chip bonding structure, and thus, the light emitting semiconductor element 120 or the light emitting module 100 may have low thermal resistance characteristics and excellent heat dissipation characteristics to improve reliability of the high-temperature performance.

The metal plate 110 may be electrically short-circuited with the light emitting semiconductor element 120 and the electric circuit wiring parts 111a and 111b. The metal plate 110 has to be in thermal contact with the bottom surface of the first plate 210 for the heat dissipation of the light emitting semiconductor element 120 and has to be separated and short-circuited from the electrical connection path that supplies power for light emission of the light emitting semiconductor element 120. However, the metal plate 11 and the electric circuit wiring parts 111a and 111b may be electrically short-circuited by the insulating base of the electric circuit wiring part.

The metal plate 110 may be provided with through-holes corresponding to the first through-hole 250 and the second through-hole 260 for the electrical connection and fixation of the plurality of light emitting modules 100, and thus, the electrode rod part 330 and the fixing member may be inserted. An inner surface of the through-hole defined in the metal plate 110 and the electrode rod part 330 may be insulated by the insulating coating layer, and an exposed end of the metal rod part may be connected to the electric circuit wiring parts 111a and 111b.

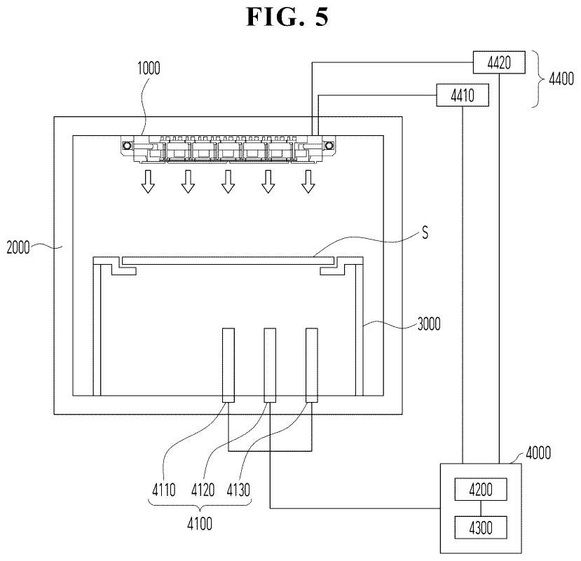

FIG. 5 is a view illustrating a configuration of an apparatus for heating a substrate according to another exemplary embodiment.

In describing an apparatus for heating a substrate according to another exemplary embodiment, details that overlap those previously described in relation to the apparatus for heating the substrate according to an exemplary embodiment will be omitted.

Referring to FIG. 5, an apparatus for heating a substrate according to another exemplary embodiment may include a chamber 2000 providing a heat treatment space, a substrate support 3000 supporting a substrate S provided in the heat treatment space, and a heater block 1000 according to an exemplary embodiment, which is provided to face the substrate support 3000 to emit light onto a first surface of the substrate S, thereby heating the substrate S.

The apparatus for heating the substrate may heat the substrate S for various processes by thermally treating the substrate S or forming a thin film on the substrate S. For example, the apparatus for heating the substrate may be a rapid thermal process (RTP) device that generates high temperature heat to rapidly perform heat treatment on the substrate S.

The chamber 2000 may provide a heat treatment space that is separated from the outside and may be controlled with various atmospheres. To prevent contamination of the substrate S, the heat treatment space may be maintained in a vacuum state, or an inert gas or the like may be introduced to be maintained under an inert atmosphere.

The substrate support 3000 may support the substrate S during the heat treatment process. The substrate support 3000 may be configured to support an edge of a lower portion of the substrate S, and thus, a portion (or area) of a bottom surface of the substrate S that is not in contact with the substrate support 3000 may be exposed. For example, the substrate support 3000 may be provided in a hollow shape having an opened center, and thus, when the substrate S is seated on the substrate support 3000, an edge portion of the bottom surface of the substrate S may be in contact with the substrate support 3000, and the remaining portion may be exposed downward.

The heater block 1000 may be the heater block according to an exemplary embodiment and thus may be provided facing the substrate support 3000 and may heat the substrate S by emitting light onto a first surface (e.g., a top surface) of the substrate S. Here, the heater block 1000 may serve to supply heat energy to the substrate S, and a plurality of light emitting modules 100 may emit light toward the first surface of the substrate S and be disposed to be spaced apart from each other on an upper side of the substrate support 3000, and thus, the light energy generated by the plurality of light emitting modules 100 may be provided through the first surface of the substrate S mounted on the substrate support 3000 to heat the substrate S.

The apparatus for heating the substrate may further include a pyrometer 4100 provided on a second surface of the substrate S opposite to the first surface to measure a temperature of the substrate S.

The pyrometer 4100 may be a pyrometer provided on the second surface (e.g., a bottom surface) opposite to the first surface of the substrate S and configured to measure the temperature of the substrate S and may detect light incident from the substrate S to measure the temperature. For example, the pyrometer 4100 may receive incident radiant light from the substrate S to measure the radiant energy (or light quantity) of the radiant light. A plurality of pyrometers 4110, 4120, and 4130 may be arranged at a lower side of the substrate S mounted on the substrate support 3000, and thus, the radiation energy and reflectivity at the facing portions may be obtained, and the temperature of the substrate S at each position (or for each area) at the corresponding positions of the pyrometers 3000 may be measured.

The apparatus for heating the substrate may further include a heating controller 4000 that selectively controls power supplied to each of the plurality of power supply modules 300 based on the temperature measured by the pyrometer 4100.

The heating controller 4000 may control the power supplied to the plurality of light emitting modules 100 corresponding to the temperature measurement positions based on the temperatures respectively measured by the plurality of pyrometers 4100. Here, the plurality of pyrometers 4100 may measure an amount of light incident from the substrate S to calculate the temperature, and the heating controller 4000 may control power input to the plurality of corresponding light emitting modules 100 using the calculated temperature.

The heating controller 4000 may include a temperature setting part 4200 that sets a target temperature of the substrate S and a power determination part 4300 that compares the target temperature set in the temperature setting part 4200 with the temperature measured by the pyrometer 4100 to determine a power supply value. The temperature setting part 4200 may set the target temperature of the substrate S and also may set the temperature of the substrate S to be achieved through the heating by the heater block 1000.

The power determination part 4300 may determine the power supply value by comparing the target temperature set in the temperature setting part 4200 with the temperature measured by the pyrometer 4100 and may supply the determined power from the power supply 4400. The power supply 4400 may include a first power supply 4410 and a second power supply 4420 that independently or selectively supply power to a first light emitting part and a second light emitting part that are provided in the light emitting module 100 and emit light independently of each other. As a result, the determined power may be supplied to the light emitting module 100 disposed on an area of the heater block 1000 corresponding to (or opposite to) a portion of the substrate S measured by the pyrometer 4110 to 4130, thereby controlling a heating temperature of the area and compensating for the temperature of the portion of the substrate S measured by the pyrometer 4110 to 4130.

The heating controller 4000 may simultaneously control the entire plurality of light emitting modules 100 according to the measured temperature or may divide the plurality of light emitting modules 100 into a plurality of groups (for example, a central area group and an edge area group, etc.) according to the temperature of each portion of the substrate S corresponding to the position provided by each of the plurality of pyrometers 4110 to 4130 to independently control an operation and power supply for each group. Likewise, the first and second light emitting parts provided in the light emitting module 100 may be controlled simultaneously as a whole or may be controlled for each group after being grouped.

As described above, In the apparatus for heating the substrate according to the exemplary embodiment, the heating temperature of the plurality of light emitting modules arranged two-dimensionally using the temperature measured by the pyrometer may be controlled to improve the temperature uniformity of the substrate during the heat treatment process. Here, the pyrometer may be provided in plurality and thus be provided for each area, and the plurality of light emitting modules may be more precisely controlled for each of the sub-divided areas based on the temperature measured by each of the plurality of pyrometers to improve the process characteristics such as the superior temperature uniformity of the substrate.

In the heater block and the apparatus for heating the substrate having the same according to the exemplary embodiments, the heat generated from the plurality of light emitting modules and the plurality of power supply modules may be effectively removed due to the simply assembled structure of the plurality of light emitting modules and the plurality of power supply modules, which are provided centered on the cooling plate. Therefore, the reduction in power of the light emitting modules and the instability in power supply, which may be caused by the insufficient heat dissipation, may be solved.

In addition, the plurality of power supply modules may independently supply the power to each to the plurality of corresponding light emitting modules to selectively control the plurality of light emitting modules, and thus, the heating temperature may be adjusted by distinguishing the positions of the plurality of light emitting modules to improve the heating uniformity of the heated object such as the substrate. In addition, at least one of the first light emitting part or the second light emitting part, which constitutes each of the plurality of light emitting modules to independently emits the light may be divided into the plurality of control areas to be independently controlled, and thus, the control areas may be sub-divided to further improve heating uniformity for the heated object.

In addition, the light emitting semiconductor element, which is the heat source or light source of the heater block, may be directly flip-chip bonded to the terminal part of the electric circuit wiring part to respond to a vacuum process that is impossible in the typical wire bonding. In addition, the output may easily increase, and also, the damage of the circuit wiring (including wires) for supplying the power may be prevented. Particularly, when the vertical-cavity surface-emitting laser (VCSEL) of the light emitting semiconductor elements is used, the power consumption compared to the typical halogen lamp or the general light emitting diode (LED) may be reduced to effectively control the optical characteristics due to the linearity of the light and the easy emission of the specific wavelength.

In the apparatus for heating the substrate according to the exemplary embodiment, the heating temperature of the plurality of light emitting modules arranged two-dimensionally using the temperature measured by the pyrometer may be controlled to improve the temperature uniformity of the substrate during the process. Here, the pyrometer may be provided in plurality and thus be provided for each area, and the plurality of light emitting modules may be precisely controlled for each of the sub-divided control areas based on the temperature measured by each of the plurality of pyrometers to improve the process characteristics such as the superior temperature uniformity of the substrate.

The term “˜on” used in the above description includes direct contact and indirect contact at a position that is opposite to an upper and lower portion. It is also possible to locate not only the entire top surface or the entire bottom surface but also the partial top surface or the bottom surface, and it is used in the mean that it is opposed in position or contact directly to upper or bottom surface. In addition, terms such as ‘top’, ‘bottom’, ‘front end’, ‘rear end’, ‘upper’, ‘lower’, ‘upper end’, ‘lower end’, etc. used in the above description are defined based on the drawings for convenience., the shape and location of each component are not limited by this term.

Although embodiments have been described with reference to a number of illustrative embodiments thereof, the embodiments are not limited to the foregoing embodiments, and thus, it should be understood that numerous other modifications and embodiments can be devised by those skilled in the art that will fall within the spirit and scope of the principles of this disclosure. Hence, the real protective scope of the present inventive concept shall be determined by the technical scope of the accompanying claims.

What is claimed is:

1. A heater block comprising:
a cooling plate provided with a cooling passage through which cooling water flows;
a plurality of light emitting modules provided on a first surface of the cooling plate to emit light toward an object to be heated; and
a plurality of power supply modules provided on a second surface of the cooling plate and electrically connected to the plurality of light emitting modules by passing through the cooling plate to supply power.

2. The heater block of claim 1, wherein each of the plurality of power supply modules comprises:
a terminal part connected to an external power source to receive power;
a body part configured to support the terminal part; and
an electrode rod part electrically connected to the terminal part to extend from a bottom surface of the body part,
wherein the electrode rod part is connected to the corresponding light emitting module by passing through the cooling plate.

3. The heater block of claim 2, wherein each of the plurality of light emitting modules comprises a first light emitting part and a second light emitting part, which emit light independently of each other,
the terminal part comprises a first terminal part and a second terminal part, which receive power supplied to the first light emitting part and the second light emitting part, respectively, and
the electrode rod part comprises a first electrode rod part and a second electrode rod part, which are electrically connected to the first terminal part and the second terminal part, respectively.

4. The heater block of claim 1, wherein the cooling plate comprises:
a first plate provided with a plurality of upper protrusions protruding from top surfaces to define a side surface of the cooling passage; and
a second plate provided on the first plate to be coupled to each other and configured to define a top surface of the cooling passage.

5. The heater block of claim 4, wherein the cooling plate further comprises a plurality of first through-holes passing through areas provided by the plurality of upper protrusions,
wherein some of the plurality of power supply modules are inserted into the plurality of first through-holes so as to be electrically connected to the plurality of corresponding light emitting modules.

6. The heater block of claim 4, wherein the cooling plate comprises:
a plurality of second through-holes passing through areas provided by the plurality of upper protrusions; and
a plurality of fixing members that are at least partially inserted into the plurality of second through-holes to fix the plurality of light emitting modules or the plurality of power supply modules.

7. The heater block of claim 4, wherein the first plate further comprises a lower protrusion protruding from a bottom surface to define a recess in which each of the plurality of light emitting modules is mounted.

8. The heater block of claim 1, wherein each of the plurality of light emitting modules and the plurality of power supply modules has a polygonal shape.

9. The heater block of claim 1, wherein the plurality of light emitting modules and the plurality of power supply modules are arranged two-dimensionally to provide an array shape having a honeycomb structure.

10. The heater block of claim 1, wherein each of the plurality of light emitting modules comprises:
a light emitting semiconductor element configured to emit light;
an electric circuit wiring part configured to transmit the power supplied from the plurality of power supply modules to the light emitting semiconductor element; and
a metal plate configured to support the electric circuit wiring part and made of a thermal conductive metal.

11. The heater block of claim 10, wherein the light emitting semiconductor element comprises a vertical-cavity surface-emitting laser element and is flip-chip bonded to the electric circuit wiring part.

12. The heater block of claim 10, wherein the metal plate is electrically short-circuited with the light emitting semiconductor element and the electric circuit wiring part.

13. The heater block of claim 1, further comprising a heat dissipation pad provided between the cooling plate and the plurality of light emitting modules and having elasticity.

14. An apparatus for heating a substrate, comprising:
a chamber configured to provide a heat treatment space;
a substrate support configured to support the substrate provided in the heat treatment space; and
the heater block of claim 1, which is provided to face the substrate support so as to emit light to a first surface of the substrate and heat the substrate.

15. The apparatus of claim 14, further comprising a pyrometer provided on a second surface of the substrate facing the first surface to measure a temperature of the substrate.

16. The apparatus of claim 15, further comprising a heating controller configured to selectively control the power supplied to each of the plurality of power supply modules based on the temperature measured by the pyrometer.
